(19) United States
(12) Patent Application Publication
(10) Pub. No.: US 2014/0218107 A1
(43) Pub. Date: Aug. 7, 2014

(54) METHOD AND APPARATUS FOR APPLYING PREDISTORTION TO AN INPUT SIGNAL FOR A NONLINEAR POWER AMPLIFIER

(71) Applicant: QUALCOMM INCORPORATED, San Diego, CA (US)

(72) Inventors: Jifeng Geng, San Diego, CA (US); Daniel Fred Filipovic, Solana Beach, CA (US)

(73) Assignee: QUALCOMM INCORPORATED, San Diego, CA (US)

(21) Appl. No.: 13/758,816

(22) Filed: Feb. 4, 2013

(51) Int. Cl. H03F 1/32

(52) U.S. Cl. CPC H03F 1/3241
USPC 330/149

(57) ABSTRACT

Aspects disclosed herein relate to providing an efficiently predistorted input signal to a high-efficiency PA. A wireless communications device may be include a power amplifier and a processor that is associated with a predistortion module. In an aspect, the processor may be a modem, a RF chip, etc. In one example, the pre-distortion module may be configured to receive an input signal and a supply voltage associated with the input signal. The predistortion module may be further configured to apply predistortion to the input signal using a linear manipulation associated with the predistortion lookup table. In an aspect, the linear manipulation may adjust the input signal based on one or more non-linear device characteristics associated with the supply voltage.

### BACKGROUND

1. Field

The disclosed aspects relate generally to enabling communications using a power amplifier PA and specifically to methods and systems for applying a linear approximation of two-dimensional predistortion to an input signal for a nonlinear power amplifier.

2. Background

Current power amplifier (PA) control apparatuses and methods are generally configured to use one or more combination of four PA control schemes. First, a battery direct scheme directly connects the battery to the PA. This may be efficient at times when max power is needed, but at lower powers efficiency drops rapidly because it's not necessary to use full battery voltage. Second, an average power tracking (APT) scheme uses a third party switcher between the batter and PA and uses an algorithm to change voltage between power control groups. Compared to the battery direct scheme, at lower powers efficiency falls off more gradually since PA voltage is correspondingly decreased. Third, a super APT (SAPT) scheme uses an algorithm to change voltage per various power control groups and also uses predistortion and adaptiveness to squeeze voltage to limits. Fourth, envelope tracking (ET) uses a separate chipset to track the signal envelope at high speed and high precision. This scheme may require PAs optimized for ET usage and may require an ET digital to analog converter (DAC) on the mobile station modem (MSM).

Further, Power amplifiers typically do not behave in a linear manner. More particularly, power amplifier distortion may compress or may expand the output signal swing of the amplifier. Signal detectors receiving and decoding the amplified signals typically do not operate in such a non-linear fashion. Therefore, it is typically necessary to linearize the output of the amplifier.

One approach to such linearization is digital predistortion. Digital predistorters may be used with power amplifiers to invert the power amplifier distortion characteristics by expanding the compression regions and compressing the expansion regions in the power amplifier characteristics curve. For example, when a power amplifier compresses a waveform, the power amplifier typically compresses the peaks of the waveform. In such a case, digital predistortion may compensate for the compression by performing crest enhancement.

Digital predistortion algorithms may require time to adapt to a given amplifier. As such, it is desired to improve the efficiency of digital predistortion algorithms so as to reduce the amount of time needed to adapt to the amplifier.

As such, a system and apparatus that provides efficiently pre-distorted signals to high-efficiency PA control without the limitations discussed above may be desired.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

Various aspects are described in connection with providing an efficiently predistorted input signal to a high-efficiency PA. A wireless communications device may be include a power amplifier and a processor that is associated with a predistortion module. In an aspect, the processor may be a modem, a RF chip, etc. In one example, the pre-distortion module may be configured to receive an input signal and a supply voltage associated with the input signal. The predistortion module may be further configured to apply predistortion to the input signal using a linear manipulation associated with the predistortion lookup table. In an aspect, the linear manipulation may adjust the input signal based on one or more non-linear device characteristics associated with the supply voltage.

According to related aspects, a method provides a mechanism for providing an efficiently predistorted input signal to a high-efficiency PA. The method can include receiving an input signal and a supply voltage associated with the input signal. Moreover, the method can include applying predistortion to the input signal using a linear manipulation associated with a predistortion lookup table. In an aspect, the linear manipulation may adjust the input signal based on one or more non-linear device characteristics associated with the supply voltage.

Another aspect relates to a communications apparatus. The wireless communications apparatus can include means for receiving an input signal and a supply voltage associated with the input signal. Moreover, the communications apparatus can include means for applying predistortion to the input signal using a linear manipulation associated with a predistortion lookup table. In an aspect, the linear manipulation may adjust the input signal based on one or more non-linear device characteristics associated with the supply voltage.

Another aspect relates to a communications apparatus. The apparatus can include a one or more predistortion modules, and one or more two-dimensional predistortion lookup table coupled to at least one of the one or more predistortion modules. Further, the predistortion modules may be configured to receiving an input signal and a supply voltage associated with the input signal, and apply predistortion to the input signal using a linear manipulation associated with a predistortion lookup table. In an aspect, the linear manipulation may adjust the input signal based on one or more non-linear device characteristics associated with the supply voltage.

Another aspect relates to a computer program product, which can have a computer-readable medium comprising code for receiving an input signal and a supply voltage associated with the input signal. Moreover, the computer-readable medium can also include code for applying predistortion to the input signal using a linear manipulation associated with a predistortion lookup table. In an aspect, the linear manipulation may adjust the input signal based on one or more non-linear device characteristics associated with the supply voltage.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a functional block diagram of an example transmitter including a modem and a power amplifier, according to an aspect;

FIG. 2 is an example schematic diagram of a processor controlled power amplifier switcher, according to an aspect;

FIG. 3 is a graphical representation of multiple amplitude to amplitude curves, according to an aspect;

FIG. 4 is a flowchart diagram describing an example for using a processor controlled switcher architecture with a high-efficiency power amplifier, according to an aspect;

FIG. 5 is a functional block diagram example architecture of a communications device, according to an aspect; and

FIG. 6 is a functional block diagram of an example communication system for providing an efficiently predistorted input signal to a high-efficiency PA, according to an aspect.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

A transmitter including a processor, a PA, and a PA switcher, coupled to the processor and PA, is described herein. As described herein, the processor may be a modem, a RF chip, etc. The PA switcher may be configured to receive, from the processor, a switcher control signal on a control line, and select from a plurality of voltage paths to provide a supply voltage to low pass filter than may provide a smoothed supply voltage to the power amplifier. In an aspect, the plurality of voltage paths may include one or more voltage source paths, a ground voltage path, etc. In an aspect, the switch control signal may indicate which path to use based on future characteristic of the input signal. The transmitter may be used for various electronic devices such as wireless communication devices, cellular phones, personal digital assistants (PDAs), handheld devices, wireless modems, laptop computers, cordless phones, Bluetooth devices, consumer electronic devices, etc. For clarity, the use of the transmitter in a wireless communication device is described below.

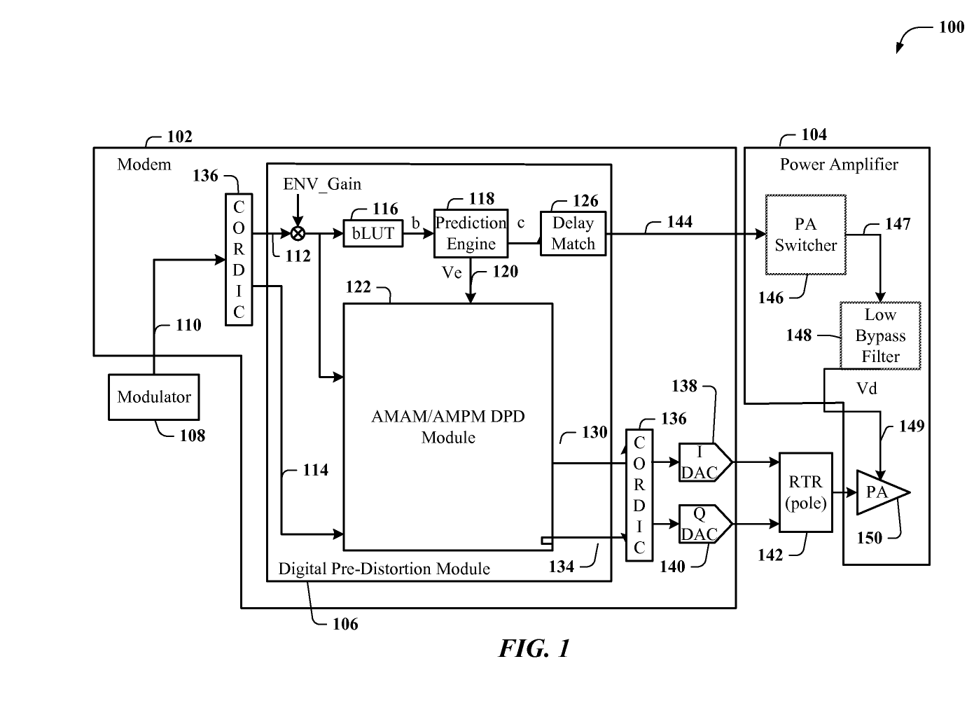

FIG. 1 illustrates a functional block diagram of an example transmitter 100 with modem 102 and PA component 104. Modem 102 may include a digital pre-distortion (DPD) module 106. PA component 104 may include PA switcher 146 that is configured to provide a supply voltage 147 to a low pass filter 148. Low pass filter 148 may process the supply voltage to generate a smoothed supply voltage 149 for PA 150.

Modem 102 may further include a coordinate rotation digital computer (CORDIC) component 136 that may be configured to receive a signal 110 from a modulator 108 and divide the signal 110 into an amplitude component 112 and a phase component 114. DPD module 106 may process amplitude component 112 and phase component 114 to produce a pre-distorted amplitude component 130 and a pre-distorted phase component 134. The pre-distorted amplitude 130 and phase 134 components may be processed by CORDIC 136 and converted to amplitude and phase components of an analog signal using “I” digital to analog converter 138 (I DAC) and “Q” DAC 140, respectively. The analogs signal components may be combined through a radio transceiver (RTR) 142 and provided to PA 150.

Within DPD module 106, the amplitude component 112 may be split, with a path (e.g., “b” path) leading to a prediction engine 118 and another path leading to an amplitude to amplitude (AMAM)/amplitude to phase (AMPM) DPD module 122.

In operation, the amplitude component 112 may be processed using AMAM/AMPM DPD module 122 to generate the pre-distorted amplitude component 130. In another aspect, the phase component 114 may be processed using AMAM/AMPM DPD module 122 to generate the pre-distorted phase component 134.

In another aspect, prior to being received by prediction engine 118, a gain associated with the amplitude component 112 (“b” path) may be modified using a LUT (e.g., bLUT) 116. Prediction engine 118 may then receive the modified amplitude component 112 and may determine an estimated voltage 120 for signal 110 and a control signal 144 for PA switcher 146. In an aspect, the received component 112 may include one or more state register values. In an aspect, prediction engine 118 may compare received component 112 (e.g., V(k)) and a lower bound value (b(k)) at time (t) and if any V(k) is within a tolerance (tol) of b(k), then prediction engine 118 may determine that a supply voltage control signal value 144 for time (t) equals “1” (e.g., the control signal 144 prompts PA switcher 146 to use a path with a voltage supply). By contrast, where V(k) at time t does not fall within the tolerance for any b(k) value, then a supply voltage control signal value 144 for time (t) may equal “0” (e.g., the control signal 144 prompts PA switcher 146 to use a path with a voltage ground). Further, in operation, the control signal 144 may pass through a delay match 126 (e.g., buffer) so as to match the arrival of the analog signal at the PA 150 with the smoothed supply voltage 14 from the low pass filter 148. In an aspect, a state register may be updated for a time (t) plus a time increment (dt) and the prediction engine 118 may estimate a voltage (Ve) value 120 for a future time (V(k)=V(k+1)−h(k), Vd=V(1) when Vs(t)=0, and V(k)=V(k+1)−h(k)+h(k+1), Vd=V(1)+h(1) when Vs(t)=1).

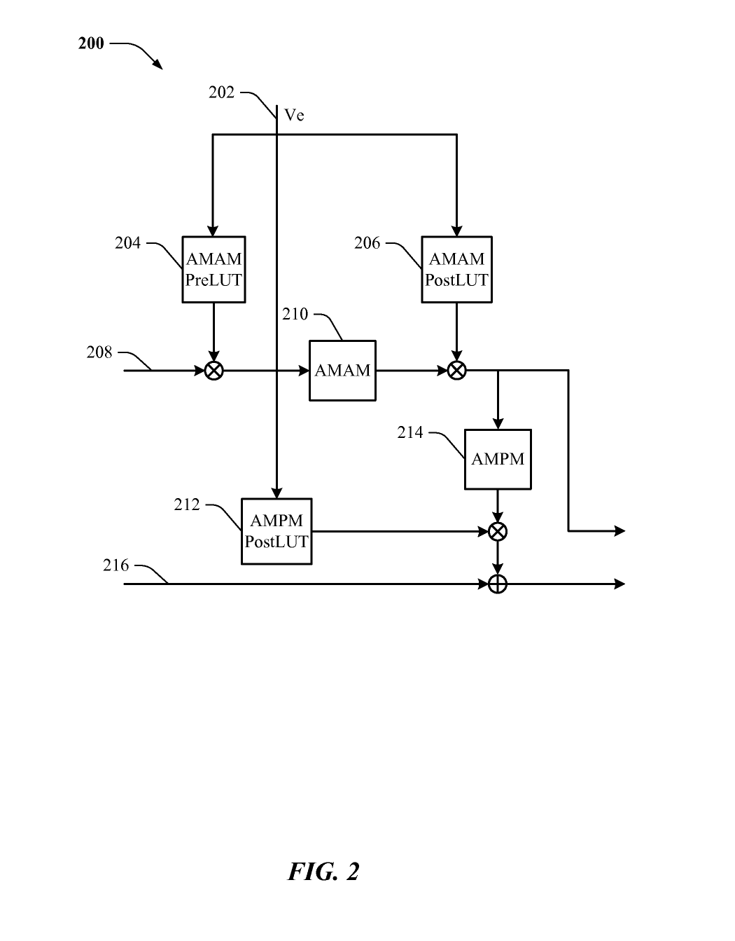

FIG. 2 illustrates an example schematic diagram of a digital predistortion (DPD) architecture 200 within a modem.

DPD architecture 200 may include an AMAM module 210 and an AMPM module 214. AMAM module 210 may be associated with a pre AMAM look up table (LUT) 204 and an AMAM post-LUT 206. Further, AMPM module 214 may be associated with an AMPM post-lookup table 212.

In operation, DPD architecture 200 may receive a various inputs including a predicted supply voltage value 202, an amplitude component 208 of an input signal and a phase component of an input signal 216. In one aspect, the predicted supply voltage value 202 may be maintained above a minimum value to assist in controlling receiver band noise by maintaining the linearity with predistortion. The predicted supply voltage value 202 may be provided to the various LUTs (204, 206, 212). The LUTs may use the predicted supply voltage value 202 to approximate one or more nonlinear AMAM curves and/or AMPM curves into linear approximations. Using the linear approximations, the amplitude component 208 of the input signal may be modified by AMAM preLUT 204 prior to manipulation by AMAM module 210 and then may be modified by AMAM pre-LUT 206. Similarly, the phase component of the input signal 216 may be modified through addition of a portion that was manipulated by AMAP module 214 and modified by AMPM post-LUT 212.

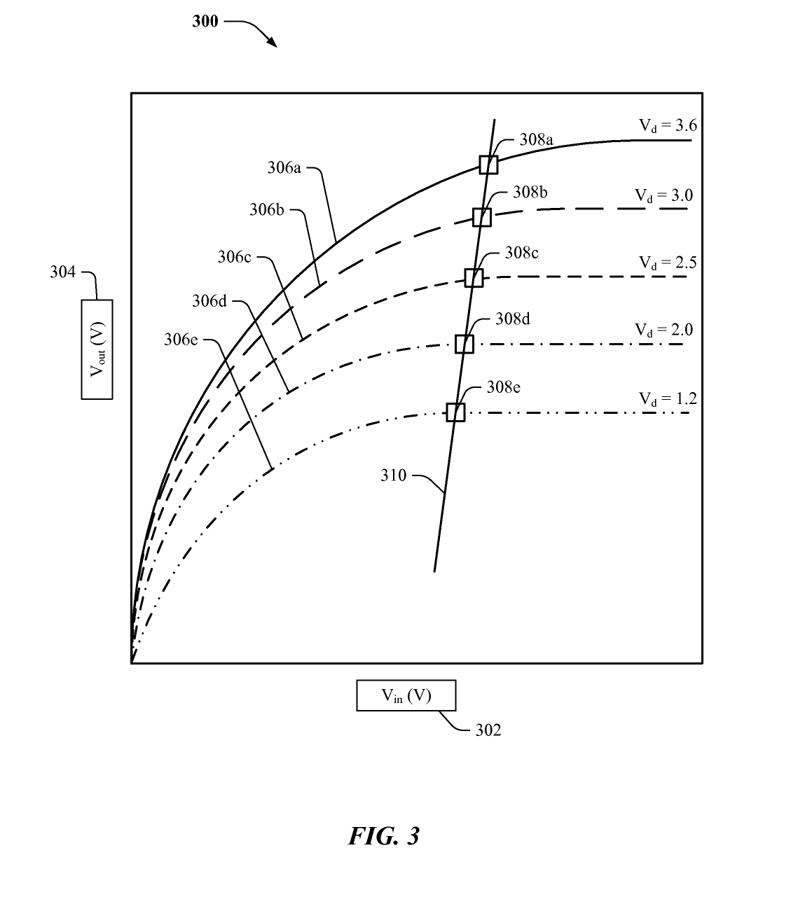

FIG. 3 illustrates a graphical representation 300 of multiple amplitude to amplitude (AMAM) curves for use in digital predistortion, according to an aspect.

Graphical representation 300 includes an x-axis 302 representing input voltage (Vᵢₙ) values. In the depicted graph, the input voltages are represented in Volts. Graphical representation 300 further includes a y-axis 304 representing output voltage (Vₒᵤₜ) values. In the depicted graph, the output voltages are represented in Volts. Further, various AMAM curves (306a-c) are depicted for various supply voltage values (e.g., V_{d}=3.6, V_{d}=3.0, V_{d}=2.5, V_{d}=2.0, V_{d}=1.2, etc.). Further, for each AMAM curve (306a-c), a point (308a-c) may be found on the AMAM curve (e.g., 306a) where the curve of one AMAM curve (e.g., 306a) may be linearly stretched to closely match the AMAM curve (e.g., 306b) at another V_{d} value. The points 308a-c may be expressed as a function of V_{d}, the input signal and an output voltage. As such, linear scaling, with respect to the input signal and output voltage, may collapse multiple AMAM curves (306a-c) to a single line 310. Although not depicted, one of ordinary skill in the art would appreciate that the linear scaling process performed on multiple AMAM curves may be applied in other context, such as but not limited to, multiple amplitude to phase (AMPM) curves.

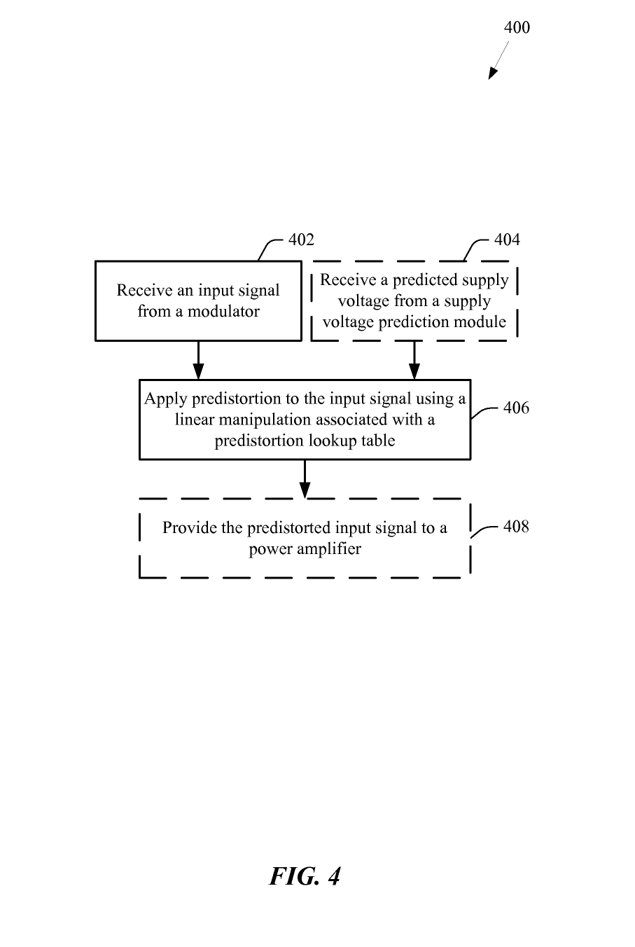

FIG. 4 illustrates methodologies in accordance with various aspects of the presented subject matter. While the methodologies are shown and described as a series of acts or sequence steps for the purposes of simplicity of explanation, it is to be understood and appreciated that the claimed subject matter is not limited by the order of acts, as some acts may occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with the claimed subject matter. Additionally, it should be further appreciated that the methodologies disclosed hereinafter and throughout this specification are capable of being stored on an article of manufacture to facilitate transporting and transferring such methodologies to computers. The term article of manufacture, as used herein, is intended to encompass a computer program accessible from any computer-readable device, carrier, or media.

FIG. 4 illustrates a flowchart 400 describing a method for applying linear approximation to two-dimensional predistortion for an input signal for a nonlinear power amplifier.

At block 402, a predistortion module may receive an input signal (envelope and phase) from a modulator. In an aspect, the input signal may be received from a buffer that may be configured to align reception of the input signal with reception of a predicted supply voltage.

In an optional aspect, at block 404, the predistortion module may receive a predicted supply voltage associated with the input signal. In one aspect, the predicted supply voltage may be received from a supply voltage prediction module.

At block 406, the predistortion module may apply predistortion to the input signal using a linear manipulation associated with a predistortion lookup table. In one aspect, the linear manipulation may include a scaling of the input signal, a shifting of the input signal, etc. In another aspect, the linear manipulation may adjust the input signal based on non-linear device characteristics associated with the received supply voltage. In such an aspect, the non-linear device characteristics may include an amplitude of the input signal, a phase of the input signal. In an aspect, the linear manipulation may scale one or more nonlinear AMAM curves with one or more linear approximations. In an aspect, the linear manipulation may scale one or more nonlinear AMPM curves with one or more linear approximations. In another aspect, the predistortion module applies values that may be interpolated between one or more additional predistortion look up tables.

At block 408, the predistortion module may provide the predistorted signal to a power amplifier to be transmitted by a communications device.

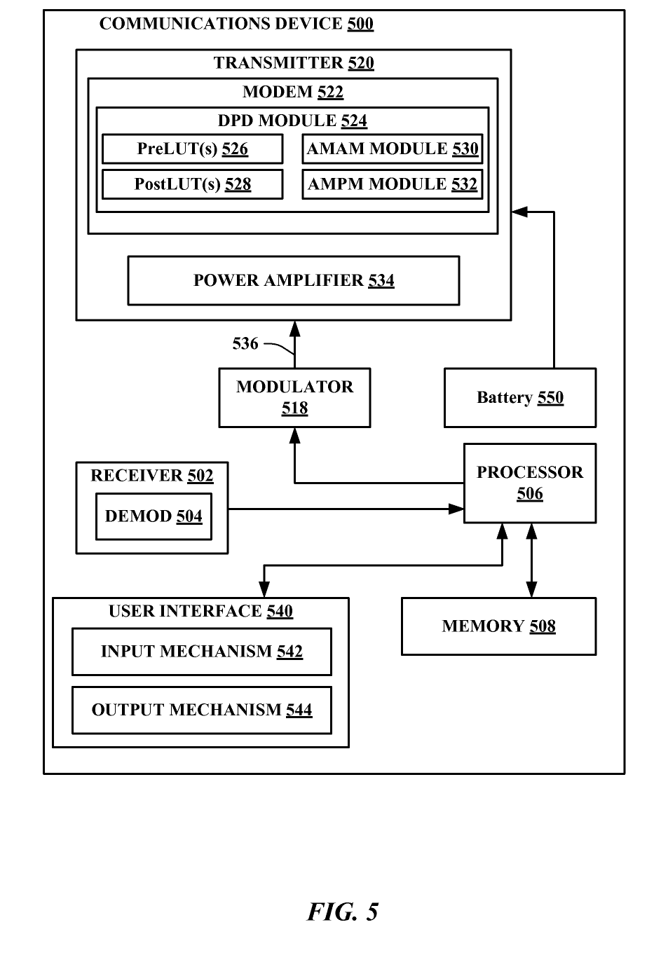

FIG. 5 illustrates an example architecture of communications device 500. As depicted in FIG. 5, communications device 500 includes receiver 502 that receives a signal from, for instance, a receive antenna (not shown), performs typical actions on (e.g., filters, amplifies, downconverts, etc.) the received signal, and digitizes the conditioned signal to obtain samples. Receiver 502 can include a demodulator 504 that can demodulate received symbols and provide them to processor 506 for channel estimation. Processor 506 can be a processor dedicated to analyzing information received by receiver 502 and/or generating information for transmission by transmitter 520, a processor that controls one or more components of communications device 500, and/or a processor that both analyzes information received by receiver 502, generates information for transmission by transmitter 520, and controls one or more components of communications device 500. Further, signals may be prepared for transmission by transmitter 520 through modulator 518 which may modulate the signals processed by processor 506.

Communications device 500 can additionally include memory 508 that is operatively coupled to processor 506 and that can store data to be transmitted, received data, information related to available channels, TCP flows, data associated with analyzed signal and/or interference strength, information related to an assigned channel, power, rate, or the like, and any other suitable information for estimating a channel and communicating via the channel. Communications device 500 can additionally include a power supply (e.g., battery 530, power supply interface, etc.).

Further, at least one of processor 506, modem 522, or transmitter 520 can provide means for receiving an input signal and a supply voltage associated with the input signal, and means for applying predistortion to the input signal using a linear manipulation associated with a predistortion lookup table (526, 528). In an aspect, the linear manipulation may adjust the input signal based on one or more non-linear device characteristics associated with the supply voltage.

It will be appreciated that data store (e.g., memory 508) described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable PROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Memory 508 of the subject systems and methods may comprise, without being limited to, these and any other suitable types of memory.

Communications device 500 transmitter 520 may include modem 522 and power amplifier 534. In an aspect, modem 522 may include a digital predistortion (DPD) module 524 that may be configured apply a DPD to an input signal 536 that is to be transmitted, to account for distortion resulting from power amplification. In such an aspect, power amplifier 534, powered at least in part by battery 550, amplifier the pre-distorted input signal 536 for transmission by transmitter 520. In another aspect, DPD module may be separate from modem 522 and associated with another processor (e.g., processor 506, RF chip, etc.). In an aspect, DPD module 524 may pre-distort the input signal 536 using AMAM module 530 and/or AMPM module 532 along with one or more AMAM and/or AMPM pre-look up tables (LUTs) 526 and post-LUTs 528. In such an aspect, the pre-LUTs 526 and/or post-LUTs 528 may include two-dimensional look-up tables. In an aspect, the DPD module 524 may provide an estimated supply voltage (Ve) along with the input signal (Vin) 536 to AMAM module 530. In such an aspect, a linear approximation may be used to represent the one or more AMAM two-dimensional look-up tables (526, 528). For example, for each Ve value, a point may be found on an AMAM curve where the curve may be linearly stretched to closely match the AMAM curve at another Ve value. The point may be expressed as a function of Ve, the input signal 536 and an output voltage. As such, linear scaling with respect to the input signal and output voltage may collapse multiple AMAM curves to a single line. In another aspect, a linear approximation may be used to represent the AMPM two-dimensional look-up table 528. For example, for each Ve value, a point may be found on an AMPM curve where the curve may be linearly stretched to closely match the AMPM curve at another Ve value. The point may be expressed as a function of Ve, the input signal 536 and an output voltage. As such, linear scaling with respect to the input signal and output voltage may collapse multiple AMPM curves to a single line. Further description of interactions within modem 522 is provided above with reference to FIGS. 1 and 2.

Additionally, communications device 500 may include user interface 540. User interface 540 may include input mechanisms 542 for generating inputs into communications device 500, and output mechanism 544 for generating information for consumption by the user of the communications device 500. For example, input mechanism 542 may include a mechanism such as a key or keyboard, a mouse, a touch-screen display, a microphone, etc. Further, for example, output mechanism 544 may include a display, an audio speaker, a haptic feedback mechanism, etc. In the illustrated aspects, the output mechanism 544 may include a display configured to present media content that is in image or video format or an audio speaker to present media content that is in an audio format.

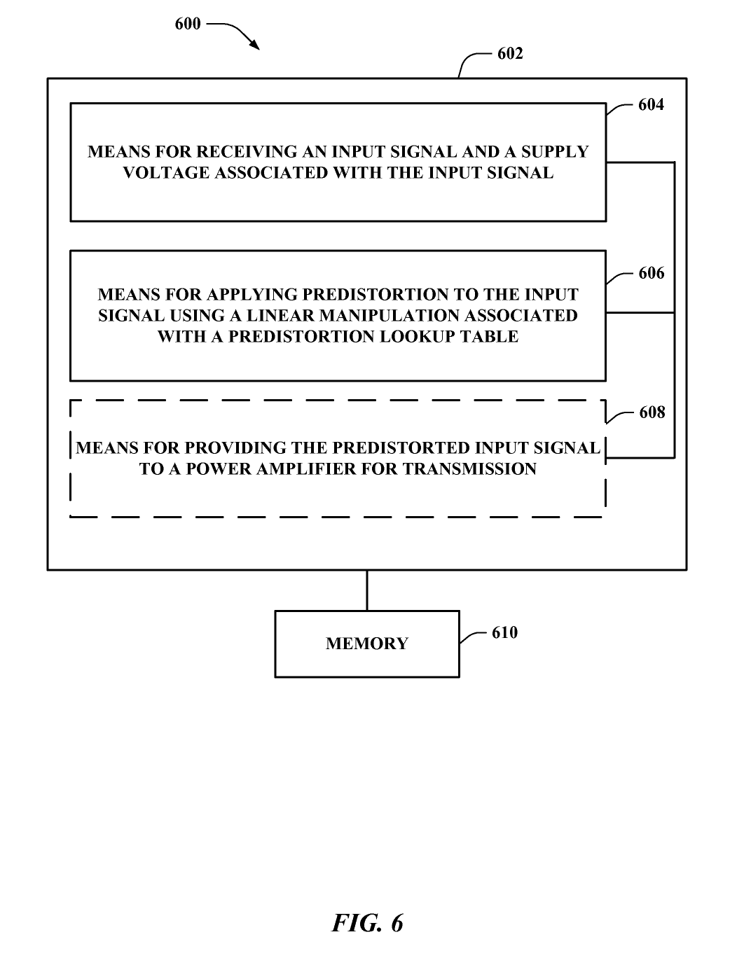

Referring to FIG. 6, an apparatus 600 that provides an efficiently predistorted input signal to a high-efficiency PA can reside at least partially within a transmitter. It is to be appreciated that apparatus 600 is represented as including functional blocks, which can represent functions implemented by a processor, software, or combination thereof (e.g., firmware).

As such, apparatus 600 includes a logical grouping 602 of electrical components that can act in conjunction. For instance, logical grouping 602 can include means for receiving an input signal and a supply voltage associated with the input signal (Block 604). In an aspect, the means for receiving 604 may include means for receiving 604 the input signal from a buffer that delays reception of the input signal from a modulator to align with reception of the predicted supply voltage. In another aspect, the means for receiving 604 may include means for receiving 604 the predicted supply voltage from a supply voltage prediction module. In another aspect, the predicted supply voltage may be based on a minimization of the supply voltage to the power amplifier. For example, in an aspect, the means 604 can include modem 522 of communications device 500 and/or processor 506 of communications device 500.

Further, logical grouping 602 can include means for applying predistortion to the input signal using a linear manipulation associated with a predistortion lookup table (Block 606). In an aspect, the linear manipulation may adjust the input signal based on one or more non-linear device characteristics associated with the supply voltage. In an aspect, the means for applying 606 may include applying one or more values that are interpolated between one or more additional predistortion look up tables. In another aspect, the means for applying 606 may include means for approximating one or more nonlinear AMAM curves with one or more linear approximations. In another aspect, the means for applying 606 may include means for approximating one or more nonlinear AMPM curves with one or more linear approximations. For example, in an aspect, the means 606 can include DPD module 524 of communications device 500 and/or processor 506 of communications device 500.

In an optional aspect, logical grouping 602 can include means for providing the predistorted input signal to a power amplifier for transmission (Block 608). For example, in an aspect, the means for providing 608 can include modem 522 of communications device 500 and/or processor 506 of communications device 500.

Additionally, apparatus 600 can include a memory 610 that retains instructions for executing functions associated with electrical components 604, 606, and 608. While shown as being external to memory 610, it is to be understood that one or more of electrical components 604, 606, and 608 can exist within memory 610. In an aspect, for example, memory 610 may be the same as or similar to memory 508 (FIG. 5).

As used in this application, the terms “component,” “module,” “system” and the like are intended to include a computer-related entity, such as but not limited to hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

Furthermore, various aspects are described herein in connection with a terminal, which can be a wired terminal or a wireless terminal. A terminal can also be called a system, device, subscriber unit, subscriber station, mobile station, mobile, mobile device, remote station, remote terminal, access terminal, user terminal, terminal, communication device, user agent, user device, or user equipment (UE). A wireless terminal may be a cellular telephone, a satellite phone, a cordless telephone, a Session Initiation Protocol (SIP) phone, a wireless local loop (WLL) station, a personal digital assistant (PDA), a handheld device having wireless connection capability, a computing device, or other processing devices connected to a wireless modem. Moreover, various aspects are described herein in connection with a base station. A base station may be utilized for communicating with wireless terminal(s) and may also be referred to as an access point, a Node B, or some other terminology.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The techniques described herein may be used for various wireless communication systems such as CDMA, TDMA, FDMA, OFDMA, SC-FDMA and other systems. The terms “system” and “network” are often used interchangeably. A CDMA system may implement a radio technology such as Universal Terrestrial Radio Access (UTRA), cdma2000, etc. UTRA includes Wideband-CDMA (W-CDMA) and other variants of CDMA. Further, cdma2000 covers IS-2000, IS-95 and IS-856 standards. A TDMA system may implement a radio technology such as Global System for Mobile Communications (GSM). An OFDMA system may implement a radio technology such as Evolved UTRA (E-UTRA), Ultra Mobile Broadband (UMB), IEEE 802.11 (Wi-Fi), IEEE 802.16 (WiMAX), IEEE 802.20, Flash-OFDM, etc. UTRA and E-UTRA are part of Universal Mobile Telecommunication System (UMTS). 3GPP Long Term Evolution (LTE) is a release of UMTS that uses E-UTRA, which employs OFDMA on the downlink and SC-FDMA on the uplink. UTRA, E-UTRA, UMTS, LTE and GSM are described in documents from an organization named “3rd Generation Partnership Project” (3GPP). Additionally, cdma2000 and UMB are described in documents from an organization named “3rd Generation Partnership Project 2” (3GPP2). Further, such wireless communication systems may additionally include peer-to-peer (e.g., mobile-to-mobile) ad hoc network systems often using unpaired unlicensed spectrums, 802.xx wireless LAN, BLUETOOTH and any other short- or long-range, wireless communication techniques.

Various aspects or features will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

The various illustrative logics, logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Additionally, at least one processor may comprise one or more modules operable to perform one or more of the steps and/or actions described above.

Further, the steps and/or actions of a method or algorithm described in connection with the aspects disclosed herein may be embodied directly in hardware, in a software module executed by a processor, or in a combination of the two. A software module may reside in RAM memory, flash memory, ROM memory, EPROM memory, EEPROM memory, registers, a hard disk, a removable disk, a CD-ROM, or any other form of storage medium known in the art. An exemplary storage medium may be coupled to the processor, such that the processor can read information from, and write information to, the storage medium. In the alternative, the storage medium may be integral to the processor. Further, in some aspects, the processor and the storage medium may reside in an ASIC. Additionally, the ASIC may reside in a user terminal In the alternative, the processor and the storage medium may reside as discrete components in a user terminal. Additionally, in some aspects, the steps and/or actions of a method or algorithm may reside as one or any combination or set of codes and/or instructions on a machine readable medium and/or computer readable medium, which may be incorporated into a computer program product.

In one or more aspects, the functions described may be implemented in hardware, software, firmware, or any combination thereof. If implemented in software, the functions may be stored or transmitted as one or more instructions or code on a computer-readable medium. Computer-readable media includes both computer storage media and communication media including any medium that facilitates transfer of a computer program from one place to another. A storage medium may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection may be termed a computer-readable medium. For example, if software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs usually reproduce data optically with lasers. Combinations of the above should also be included within the scope of computer-readable media.

While the foregoing disclosure discusses illustrative aspects and/or embodiments, it should be noted that various changes and modifications could be made herein without departing from the scope of the described aspects and/or embodiments as defined by the appended claims. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

What is claimed is:

1. A method of communications, comprising:
receiving an input signal and a supply voltage associated with the input signal; and
applying predistortion to the input signal using a linear manipulation associated with a predistortion lookup table, wherein the linear manipulation adjusts the input signal based on one or more non-linear device characteristics associated with the supply voltage.

2. The method of claim 1, wherein the linear manipulation comprises at least one of a scaling, a shifting, or any combination thereof, of the input signal.

3. The method of claim 1, wherein one of the one or more non-linear device characteristics is an amplitude of the input signal.

4. The method of claim 1, wherein one of the one or more non-linear device characteristics is a phase of the input signal.

5. The method of claim 1, wherein receiving the input signal further comprises receiving the input signal from a buffer that delays reception to align with reception of the supply voltage.

6. The method of claim 5, wherein the supply voltage comprises a predicted supply voltage from a supply voltage prediction module.

7. The method of claim 1, wherein the applying further comprising applying one or more values that are interpolated between one or more additional predistortion look up tables.

8. The method of claim 1, wherein the linear manipulation scales one or more nonlinear amplitude to amplitude (AMAM) curves with one or more linear approximations.

9. The method of claim 1, wherein the linear manipulation scales one or more nonlinear amplitude to phase (AMPM) curves with one or more linear approximations.

10. The method of claim 1, further comprising:
providing the predistorted input signal to a power amplifier for transmission.

11. An apparatus, comprising:
a predistortion lookup table; and
a predistortion module coupled to the predistortion lookup table, wherein predistortion module is configured to:
receive an input signal and a supply voltage associated with the input signal; and
apply predistortion to the input signal using a linear manipulation associated with the predistortion lookup table, wherein the linear manipulation adjusts the input signal based on one or more non-linear device characteristics associated with the supply voltage.

12. The apparatus of claim 11, wherein the linear manipulation comprises at least one of a scaling, a shifting, or any combination thereof, of the input signal.

13. The apparatus of claim 11, wherein the predistortion module is an amplitude to amplitude (AMAM) predistortion module, and wherein one of the one or more non-linear device characteristics is an amplitude of the input signal.

14. The apparatus of claim 11, wherein the predistortion module is an amplitude to phase (AMPM) predistortion module, and wherein one of the one or more non-linear device characteristics is a phase of the input signal.

15. The apparatus of claim 11, wherein the apparatus further comprises a supply voltage prediction module that includes a buffer, wherein the supply voltage prediction module is configured to:
generate a predicted supply voltage; and
provide the predicted supply voltage as the supply voltage to the predistortion module.

16. The apparatus of claim 11, wherein the predistortion module is further configured to apply one or more values that are interpolated between one or more additional predistortion look up tables.

17. The apparatus of claim 11, the predistortion module is an AMAM predistortion module, and wherein the AMAM predistortion module is configured to approximate one or more nonlinear AMAM curves with one or more linear approximations.

18. The apparatus of claim 11, the predistortion module is an AMPM predistortion module, and wherein the AMPM predistortion module is configured to approximate one or more nonlinear AMPM curves with one or more linear approximations.

19. The apparatus of claim 11, wherein the apparatus further comprises a power amplifier, and wherein the predistortion module is further configured to provide the predistorted input signal to the power amplifier.

20. A computer program product, comprising;
a computer-readable medium comprising code to:
receive an input signal and a supply voltage associated with the input signal; and
apply predistortion to the input signal using a linear manipulation associated with a predistortion lookup table, wherein the linear manipulation adjusts the input signal based on one or more non-linear device characteristics associated with the supply voltage.

21. An apparatus for signal predistortion, comprising:
means for receiving an input signal and a supply voltage associated with the input signal; and
means for applying predistortion to the input signal using a linear manipulation associated with a predistortion lookup table, wherein the linear manipulation adjusts the input signal based on one or more non-linear device characteristics associated with the supply voltage.

22. The apparatus of claim 21, wherein the linear manipulation comprises at least one of a scaling, a shifting, or any combination thereof, of the input signal.

23. The apparatus of claim 21, wherein one of the one or more non-linear device characteristics is an amplitude of the input signal.

24. The apparatus of claim 21, wherein one of the one or more non-linear device characteristics is a phase of the input signal.

25. The apparatus of claim 21, wherein means for receiving the input signal comprises means for receiving the input signal from a buffer that delays reception to align with reception of the supply voltage.

26. The apparatus of claim 25, wherein the supply voltage comprises a predicted supply voltage from a supply voltage prediction module.

27. The apparatus of claim 21, wherein the means for applying further comprising means for applying one or more values that are interpolated between one or more additional predistortion look up tables.

28. The apparatus of claim 21, wherein the linear manipulation scales one or more nonlinear amplitude to amplitude (AMAM) curves with one or more linear approximations.

29. The apparatus of claim 21, wherein the linear manipulation scales one or more nonlinear amplitude to phase (AMPM) curves with one or more linear approximations.

30. The apparatus of claim 21, further comprising:
means for providing the predistorted input signal to a power amplifier for transmission.
